(19) United States
(12) Patent Application Publication
(10) Pub. No.: US 2025/0391445 A1
(43) Pub. Date: Dec. 25, 2025

(54) SILICON RETENTION FOR TRANSISTOR FORMATION

(71) Applicant: Micron Technology, Inc., Boise, ID (US)

(72) Inventors: Darwin A. Clampitt, Wilder, ID (US); John B. Matovu, Boise, ID (US); Collin Robert Howder, Boise, ID (US); Martin Jared Barclay, Middleton, ID (US)

(21) Appl. No.: 19/234,224

(22) Filed: Jun. 10, 2025

Related U.S. Application Data
(60) Provisional application No. 63/661,838, filed on Jun. 19, 2024.

(51) Int. Cl. G11C 5/06; H10B 43/20; H10B 43/35

(52) U.S. Cl. CPC G11C 5/063; H10B 43/20; H10B 43/35

(57) ABSTRACT

Methods, systems, and devices for silicon retention for transistor formation are described. Available silicon within a storage component may be utilized to form additional supporting circuitry. For example, after the completion of one or more relatively higher heat formation processes to produce one or more arrays of memory cells in a storage component, such as a storage wafer or die, of a memory device, one or more transistors may be formed within a remaining silicon portion. Additional contacts may be formed for accessing the transistors, and the storage component may be bonded to a corresponding supporting component, such as a wafer or die including supporting circuitry. Utilizing available silicon of a storage component may increase a total amount of crystalline silicon available for supporting circuitry for a memory device, which may support increases in quantities of memory cells and other circuitry.

### CROSS REFERENCE

The present Application for Patent claims priority to U.S. Patent Application No. 63/661,838 by Clampitt et al., entitled “SILICON RETENTION FOR TRANSISTOR FORMATION,” filed Jun. 19, 2024, which is assigned to the assignee hereof, and which is expressly incorporated by reference in its entirety herein.

### TECHNICAL FIELD

The following relates to one or more systems for memory, including silicon retention for transistor formation.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports silicon retention for transistor formation in accordance with examples as disclosed herein.

FIG. 2 shows an example of a system that supports silicon retention for transistor formation in accordance with examples as disclosed herein.

FIGS. 3A-3J show examples of processing steps that support silicon retention for transistor formation in accordance with examples as disclosed herein.

FIG. 4 shows a flowchart illustrating a method or methods that support silicon retention for transistor formation in accordance with examples as disclosed herein.

### DETAILED DESCRIPTION

Some memory devices may include multiple components (e.g., dies, wafers) that may include temperature sensitive circuitry. For example, supporting circuitry, such as complementary metal-oxide-semiconductor (CMOS) transistors, may operate at relatively low voltages and may be more sensitive to higher temperatures compared to storage circuitry, such as memory cell arrays. Thus, a component including support circuitry (e.g., a CMOS wafer) may be formed using lower temperature processes separate from (e.g., independent of) one or more higher temperature processes used to form a component including storage circuitry (e.g., an array wafer), and the two components may be bonded after the higher temperature processes to prevent damage to the supporting circuitry. As storage density in memory devices increases, a quantity of access lines (e.g., word lines, bit lines) and other transistor features may also increase, which may in turn depend on a greater quantities of transistors and other supporting circuitry. However, a silicon area within a storage component used to form supporting circuitry may be limited and may lack adequate space for supporting the greater quantities of transistors as memory sizes increase.

As described herein, available silicon associated with (e.g., within) a storage component may be utilized to form additional supporting circuitry. For example, after the completion of one or more relatively higher heat formation processes to produce one or more arrays of memory cells in a storage component (e.g., an array wafer) of a memory device, one or more transistors may be formed relative to (e.g., within) a remaining silicon portion. Additional contacts may be formed for accessing the transistors, and the storage component may be bonded to a corresponding supporting component (e.g., CMOS wafer) while forming metal layers. In some examples, to support such transistors, a lateral contact source area may be formed between a silicon material and one or more memory cells (e.g., pillars of stacked memory cells). Building supporting circuitry in available silicon of a storage component may thus increase a total amount of crystalline silicon available for transistor formation of an overall memory device, which may support a greater quantity of memory cells and other circuitry to provide increased performance and memory capacity, while also improving efficiency in device design and reducing material waste in production, among other advantages.

In addition to applicability in memory systems as described herein, techniques for silicon retention for transistor formation may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by increasing an efficiency of silicon use while limiting the use of additional materials (e.g., additional silicon), which may result in lowered production emissions and reduced electronic waste, among other benefits.

In addition to applicability in memory systems as described herein, techniques for silicon retention for transistor formation may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing a quantity of supporting elements, which may increase performance of a memory device while increasing a supported memory capacity, among other benefits.

Features of the disclosure are illustrated and described in the context of systems, devices, and circuits. Features of the disclosure are further illustrated and described in the context of processing steps and flowcharts.

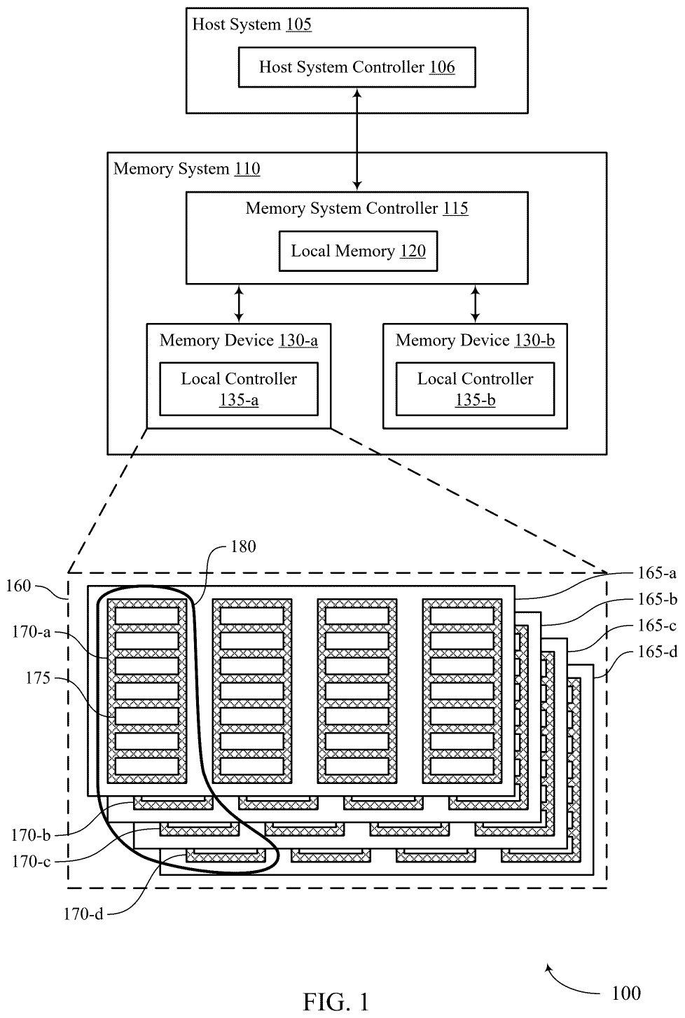

FIG. 1 shows an example of a system 100 that supports silicon retention for transistor formation in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open not-and (NAND) Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some examples, the memory system 110 may support utilization of available silicon associated with (e.g., within) a storage component to form supporting circuitry as described herein. For example, formation of an array wafer, or array die, of a memory device 130 may involve one or more relatively higher heat formation processes to produce one or more arrays of memory cells. In some examples, one or more transistors may be formed within a remaining silicon portion of the array wafer. Additional contacts may be formed for accessing the transistors, and the storage component may be bonded to a corresponding supporting wafer or die (e.g., a CMOS wafer) including supporting circuitry. In some examples, utilizing the available silicon of the storage wafer may increase a total amount of crystalline silicon available for supporting circuitry for the memory device 130, which may support increases in quantities of memory cells and other circuitry.

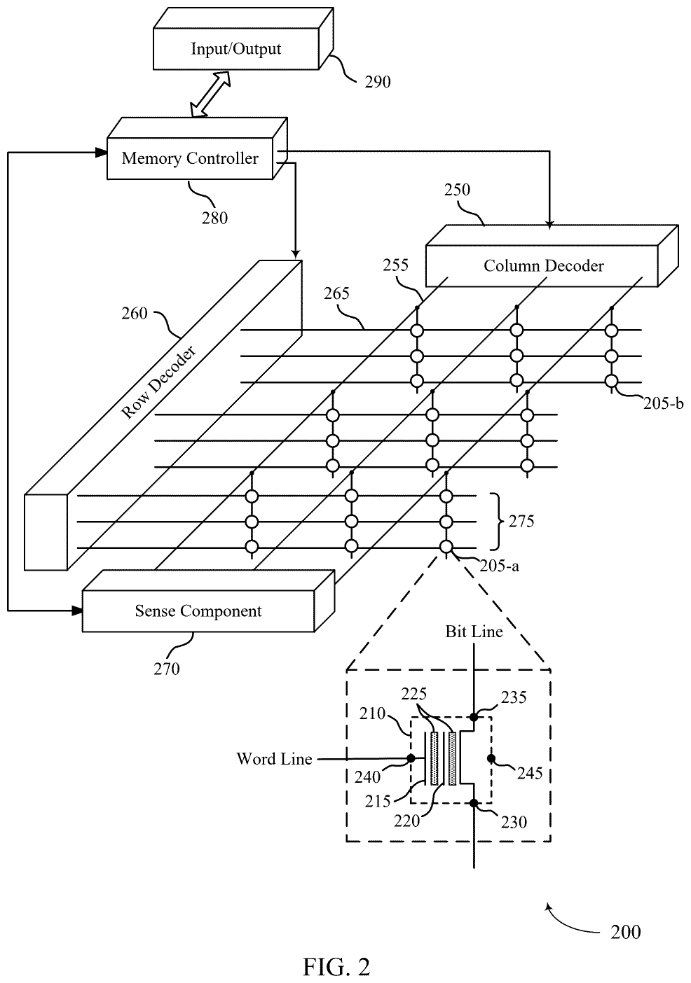

FIG. 2 shows an example of a memory device 200 that supports silicon retention for transistor formation in accordance with examples as disclosed herein. FIG. 2 is an illustrative representation of various components and features of the memory device 200. As such, the components and features of the memory device 200 are shown to illustrate functional interrelationships, and not necessarily physical positions within the memory device 200. Further, although some elements included in FIG. 2 are labeled with a numeric indicator, some other corresponding elements are not labeled, even though they are the same or would be understood to be similar, in an effort to increase visibility and clarity of the depicted features.

The memory device 200 may include one or more memory cells 205, such as memory cell 205-a and memory cell 205-b. In some examples, a memory cell 205 may be a NAND memory cell, such as in the blow-up diagram of memory cell 205-a. Each memory cell 205 may be programmed to store a logic value representing one or more bits of information. In some examples, a single memory cell 205—such as a memory cell 205 configured as a single-level cell (SLC)—may be programmed to one of two supported states and thus may store one bit of information at a time (e.g., a logic 0 or a logic 1). In some other examples, a single memory cell 205—such a memory cell 205 configured as a multi-level cell (MLC), a tri-level cell (TLC), a quad-level cell (QLC), or other type of multiple-level memory cell 205—may be programmed to one state of more than two supported states and thus may store more than one bit of information at a time. In some cases, a multiple-level memory cell 205 (e.g., an MLC memory cell, a TLC memory cell, a QLC memory cell) may be physically different than an SLC cell. For example, a multiple-level memory cell 205 may use a different cell geometry or may be fabricated using different materials. In some examples, a multiple-level memory cell 205 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 205 may be illustrated as a transistor that includes a charge trapping structure (e.g., a floating gate, a replacement gate, a dielectric material) for storing an amount of charge representative of a logic value. For example, the blow-up in FIG. 2 illustrates a NAND memory cell 205-a that includes a transistor 210 (e.g., a metal-oxide-semiconductor (MOS) transistor) that may be used to store a logic value. The transistor 210 may include a control gate 215 and a charge trapping structure 220 (e.g., a floating gate, a replacement gate), where the charge trapping structure 220 may, in some examples, be between two portions of dielectric material 225. The transistor 210 also may include a first node 230 (e.g., a source or drain) and a second node 235 (e.g., a drain or source). A logic value may be stored in transistor 210 by storing (e.g., writing) a quantity of electrons (e.g., an amount of charge) on the charge trapping structure 220. An amount of charge to be stored on the charge trapping structure 220 may depend on the logic value to be stored. The charge stored on the charge trapping structure 220 may affect the threshold voltage of the transistor 210, thereby affecting the amount of current that flows through the transistor 210 when the transistor 210 is activated (e.g., when a voltage is applied to the control gate 215, when the memory cell 205-a is read). In some examples, the charge trapping structure 220 may be an example of a floating gate or a replacement gate that may be part of a 2D NAND structure. For example, a 2D NAND array may include multiple control gates 215 and charge trapping structures 220 arranged around a single channel (e.g., a horizontal channel, a vertical channel, a columnar channel, a pillar channel).

A logic value stored in the transistor 210 may be sensed (e.g., as part of a read operation) by applying a voltage to the control gate 215 (e.g., to control node 240, via a word line 265) to activate the transistor 210 and measuring (e.g., detecting, sensing) an amount of current that flows through the first node 230 or the second node 235 (e.g., via a bit line 255). For example, a sense component 270 may determine whether an SLC memory cell 205 stores a logic 0 or a logic 1 in a binary manner (e.g., based on a presence or absence of a current through the memory cell 205 when a read voltage is applied to the control gate 215, based on whether the current is above or below a threshold current). For a multiple-level memory cell 205, a sense component 270 may determine a logic value stored in the memory cell 205 based on various intermediate threshold levels of current when a read voltage is applied to the control gate 215, or by applying different read voltages to the control gate and evaluating different resulting levels of current through the transistor 210, or various combinations thereof. In one example of a multiple-level architecture, a sense component 270 may determine the logic value of a TLC memory cell 205 based on eight different levels of current, or ranges of current, that define the eight potential logic values that could be stored by the TLC memory cell 205.

An SLC memory cell 205 may be written by applying one of two voltages (e.g., a voltage above a threshold or a voltage below a threshold) to the memory cell 205 to store, or not store, an electric charge on the charge trapping structure 220 and thereby cause the memory cell 205 to store one of two possible logic values. For example, when a first voltage is applied to the control node 240 (e.g., via a word line 265) relative to a bulk node 245 (e.g., a body node) for the transistor 210 (e.g., when the control node 240 is at a higher voltage than the bulk), electrons may tunnel into the charge trapping structure 220. Injection of electrons into the charge trapping structure 220 may be referred to as programming the memory cell 205 and may occur as part of a write operation. A programmed memory cell may, in some cases, be considered as storing a logic 0. When a second voltage is applied to the control node 240 (e.g., via the word line 265) relative to the bulk node 245 for the transistor 210 (e.g., when the control node 240 is at a lower voltage than the bulk node 245), electrons may leave the charge trapping structure 220. Removal of electrons from the charge trapping structure 220 may be referred to as erasing the memory cell 205 and may occur as part of an erase operation. An erased memory cell may, in some cases, be considered as storing a logic 1. In some cases, memory cells 205 may be programmed at a page level of granularity due to memory cells 205 of a page sharing a common word line 265, and memory cells 205 may be erased at a block level of granularity due to memory cells 205 of a block sharing commonly biased bulk nodes 245.

In contrast to writing an SLC memory cell 205, writing a multiple-level (e.g., MLC, TLC, or QLC) memory cell 205 may involve applying different voltages to the memory cell 205 (e.g., to the control node 240 or bulk node 245 thereof) at a finer level of granularity to more finely control the amount of charge stored on the charge trapping structure 220, thereby enabling a larger set of logic values to be represented. Thus, multiple-level memory cells 205 may provide greater density of storage relative to SLC memory cells 205 but may, in some cases, involve narrower read or write margins or greater complexities for supporting circuitry.

A charge-trapping NAND memory cell 205 may operate similarly to a floating-gate NAND memory cell 205 but, instead of or in addition to storing a charge on a charge trapping structure 220, a charge-trapping NAND memory cell 205 may store a charge representing a logic state in a dielectric material between the control gate 215 and a channel (e.g., a channel between a first node 230 and a second node 235). Thus, a charge-trapping NAND memory cell 205 may include a charge trapping structure 220, or may implement charge trapping functionality in one or more portions of dielectric material 225, among other configurations.

In some examples, each page of memory cells 205 may be connected to a corresponding word line 265, and each column of memory cells 205 may be connected to a corresponding bit line 255 (e.g., digit line). Thus, one memory cell 205 may be located at the intersection of a word line 265 and a bit line 255. This intersection may be referred to as an address of a memory cell 205. In some cases, word lines 265 and bit lines 255 may be substantially perpendicular to one another, and may be generically referred to as access lines or select lines.

In some cases, a memory device 200 may include a three-dimensional (3D) memory array, where multiple two-dimensional (2D) memory arrays may be formed on top of one another. In some examples, such an arrangement may increase the quantity of memory cells 205 that may be fabricated on a single die or substrate as compared with 1D arrays, which, in turn, may reduce production costs, or increase the performance of the memory array, or both. In the example of FIG. 2, memory device 200 includes multiple levels (e.g., decks, layers, planes, tiers) of memory cells 205. The levels may, in some examples, be separated by an electrically insulating material. Each level may be aligned or positioned so that memory cells 205 may be aligned (e.g., exactly aligned, overlapping, or approximately aligned) with one another across each level, forming a memory cell stack 275. In some cases, memory cells aligned along a memory cell stack 275 may be referred to as a string of memory cells 205 (e.g., as described with reference to FIG. 2).

Accessing memory cells 205 may be controlled through a row decoder 260 and a column decoder 250. For example, the row decoder 260 may receive a row address from the memory controller 280 and activate an appropriate word line 265 based on the received row address. Similarly, the column decoder 250 may receive a column address from the memory controller 280 and activate an appropriate bit line 255. Thus, by activating one word line 265 and one bit line 255, one memory cell 205 may be accessed. As part of such accessing, a memory cell 205 may be read (e.g., sensed) by sense component 270. For example, the sense component 270 may be configured to determine the stored logic value of a memory cell 205 based on a signal generated by accessing the memory cell 205. The signal may include a current, a voltage, or both a current and a voltage on the bit line 255 for the memory cell 205 and may depend on the logic value stored by the memory cell 205. The sense component 270 may include various circuitry (e.g., transistors, amplifiers) configured to detect and amplify a signal (e.g., a current or voltage) on a bit line 255. The logic value of memory cell 205 as detected by the sense component 270 may be output via input/output component 290. In some cases, a sense component 270 may be a part of a column decoder 250 or a row decoder 260, or a sense component 270 may otherwise be connected to or in electronic communication with a column decoder 250 or a row decoder 260.

A memory cell 205 may be programmed or written by activating the relevant word line 265 and bit line 255 to enable a logic value (e.g., representing one or more bits of information) to be stored in the memory cell 205. A column decoder 250 or a row decoder 260 may accept data (e.g., from the input/output component 290) to be written to the memory cells 205. In the case of NAND memory, a memory cell 205 may be written by storing electrons in a charge trapping structure or an insulating layer.

A memory controller 280 may control the operation (e.g., read, write, re-write, refresh) of memory cells 205 through the various components (e.g., row decoder 260, column decoder 250, sense component 270). In some cases, one or more of a row decoder 260, a column decoder 250, and a sense component 270 may be co-located with a memory controller 280. A memory controller 280 may generate row and column address signals in order to activate a desired word line 265 and bit line 255. In some examples, a memory controller 280 may generate and control various voltages or currents used during the operation of memory device 200.

In some examples, the memory device 200 may be formed by a manufacturing system using one or more fabrication operations. For example, the memory device 200 may include a supporting component (e.g., CMOS wafer, CMOS die) including supporting circuitry formed separately from a storage component (e.g., array wafer, array die), where the storage component may include an array of memory cells 205 (e.g., a 3D memory array of memory array stacks 275, such as 3D NAND). The supporting component may be formed separate from the storage component as described herein to support higher temperature formation processes of storage components (as some memory cells may involve higher temperature formation processes). In some examples, to form the storage component, a stack of materials may be formed that may include one or more alternating dielectric materials and conductive materials, one or more storage elements (e.g., arrays of storage pillars), one or more conductive contacts, one or more poly-silicon materials (e.g., poly-silicon slots), among other materials. The material stack may be formed on a semiconductor material (e.g., a silicon wafer), which may involve an addition of a mask and operations to form further elements within the silicon. For example, additional operations may include utilizing one or more masks (e.g., multi-layer mask (MLM), multi-layer reticle (MLR)), etch operations (e.g., dry etch, wet etch recess), metallization (e.g., etch, such as a titanium silicide (TiSix) etch with metal deposition, such as deposition of tungsten), metal removal (e.g., etch, recess), metal module operations, among other operations. After forming the material stack, wiring may be performed to add one or more metal layers on top of the semiconductor material (e.g., on an opposite side with respect to the material stack) and one or more bonding pads may be added. The material stack may be bonded to a supporting component, such as a CMOS wafer to support the memory cells formed in the storage component. In some cases, remaining silicon from the one or more formation processes may be discarded.

An increase in quantities of word lines 265 may increase one or more string driver requirements as well as other supporting transistor features. For example, as a greater quantity of memory cells 205 are implemented in larger and larger memory cell stacks 275 (e.g., with increasing layers in 3D NAND), a greater quantity of word lines 265 may be implemented, resulting in a corresponding increase in supporting circuitry. However, a supporting component bonded to a storage component may have a limited quantity of silicon. Thus, even though improvements in fabrication processes may reduce (e.g., shrink) a size of transistors on a supporting component to allow for a greater quantity of transistors, limited silicon area may at a point prevent additional formation of transistors, or reduce an efficiency or effectiveness of transistor formation, among other challenges. Thus, a supporting component size may in some cases be insufficient to supply transistors for further memory formation.

As described herein, the memory device 200 may support lateral contact sources and bonded array wafer silicon retention for transistor formation. For example, after one or more higher heat processes are complete for the storage component (e.g., array formation is complete and post bonding), a thinned silicon array wafer may be used to supply low thermal budget transistor formation in addition to bonding interconnect function. For example, a planarizing process may expose a crystalline silicon of the wafer for formation of one or more devices before forming metal layers and bonding pads, where one or more transistors may be formed within the exposed silicon. Further transistors may also be formed during one or more previous or later steps (e.g., at another side of the silicon material). In some examples, backside lateral contact source formation may further be performed below a thinned crystalline silicon wafer layer once transistors are built. The operations described herein may enable an amount of crystalline silicon available for transistor formation to be increased (e.g., doubled) for a given die size while reducing material waste.

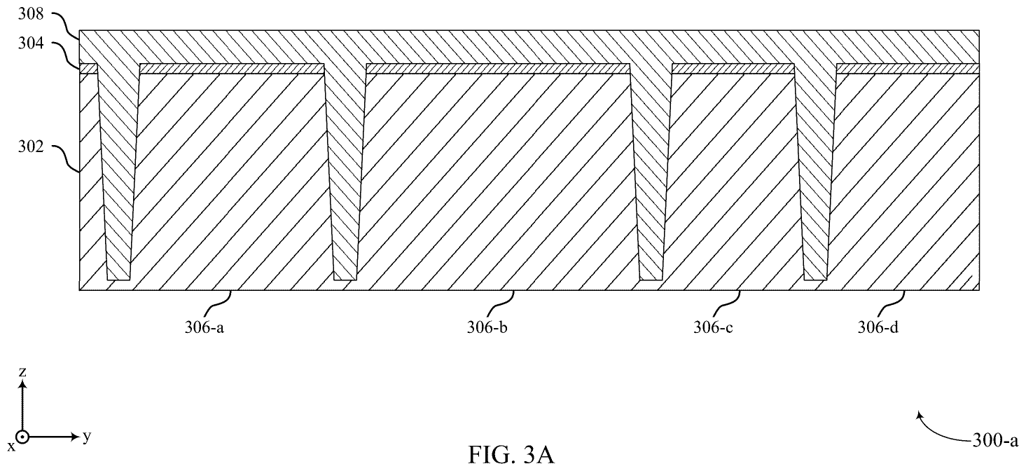

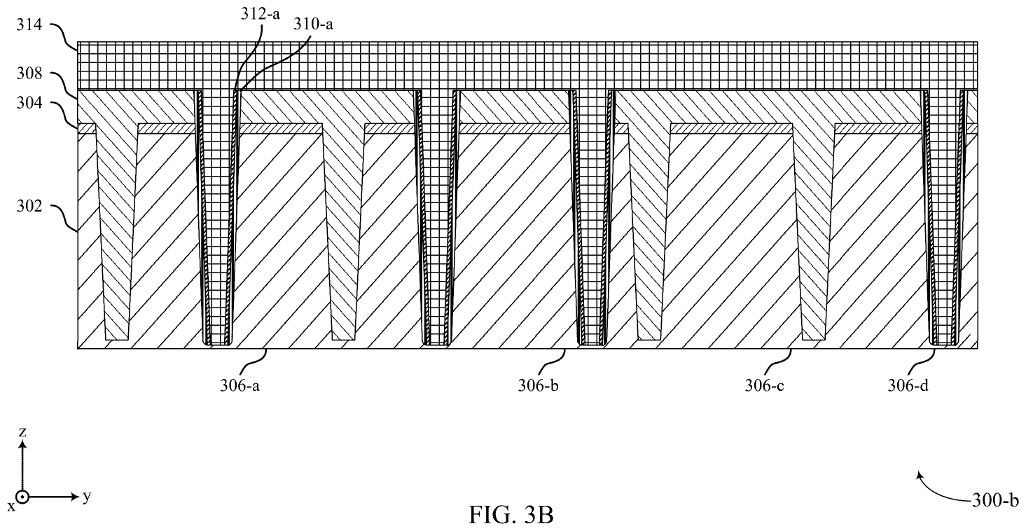

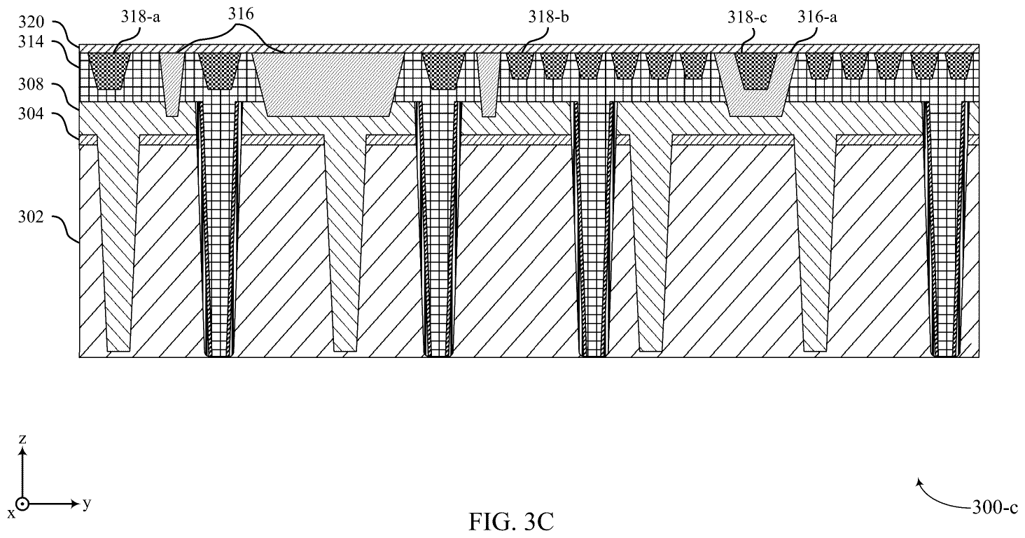

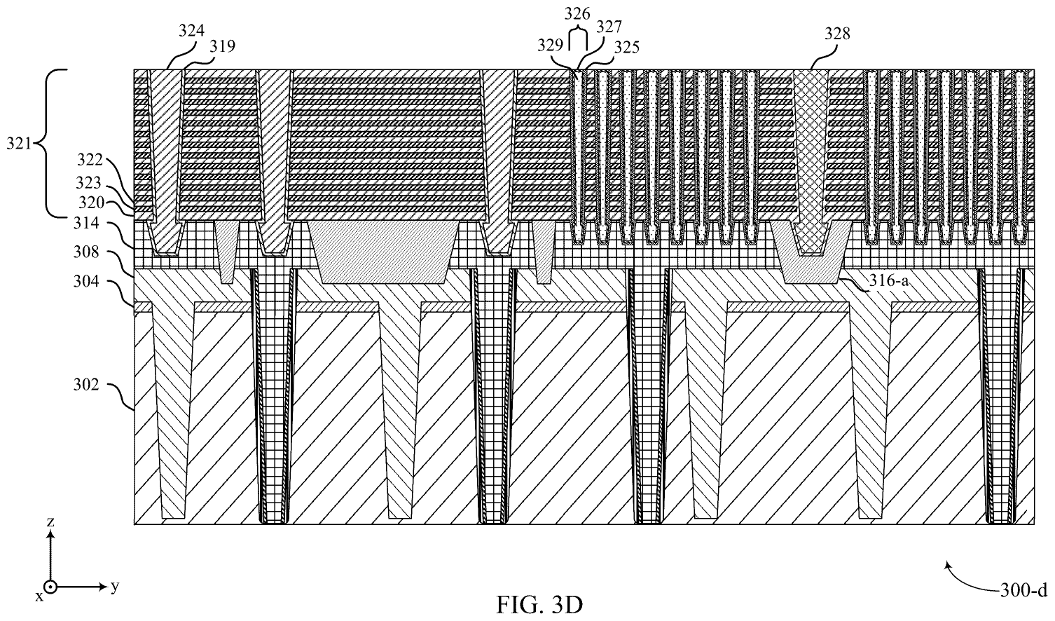

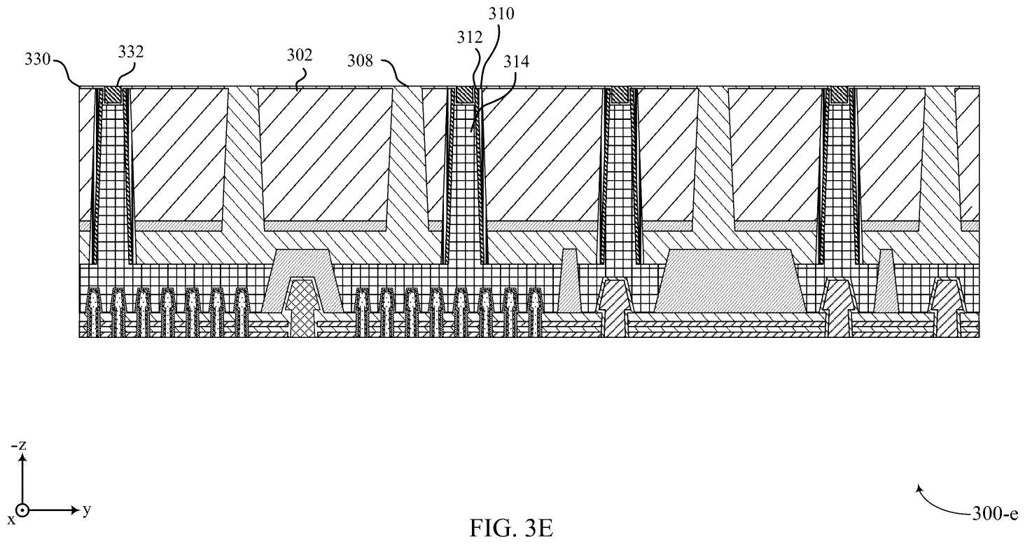

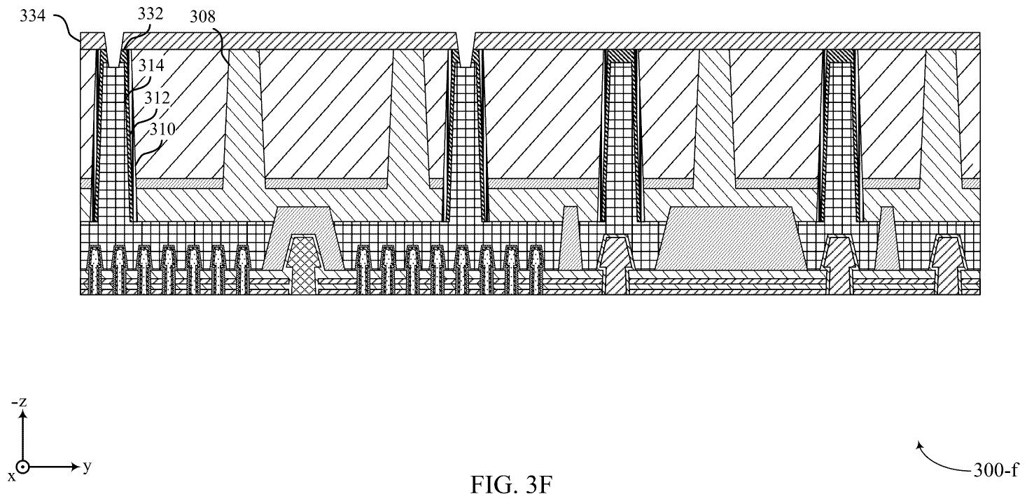

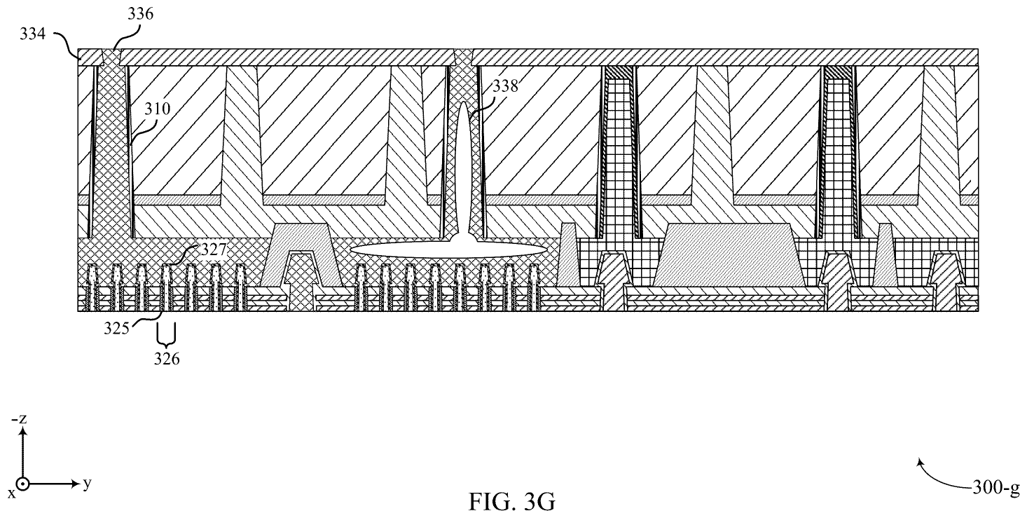

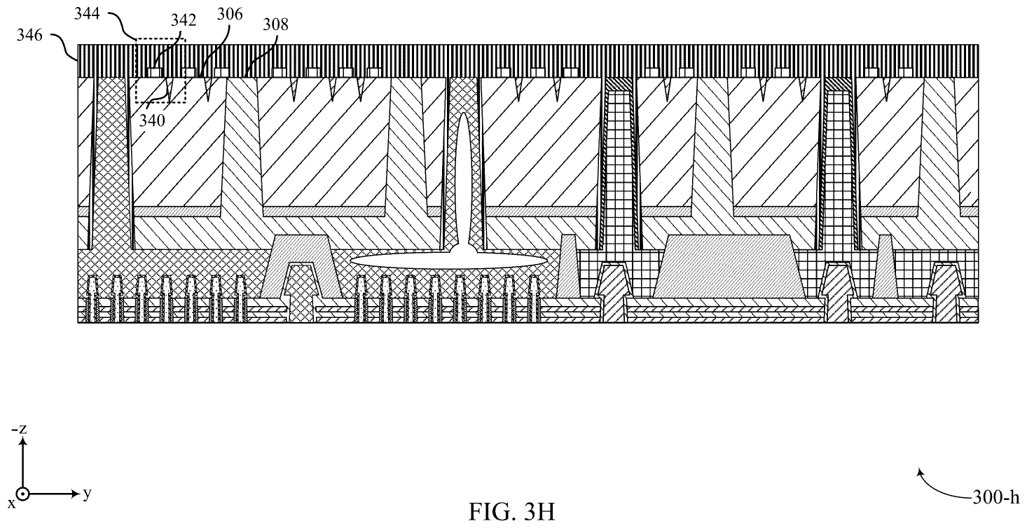

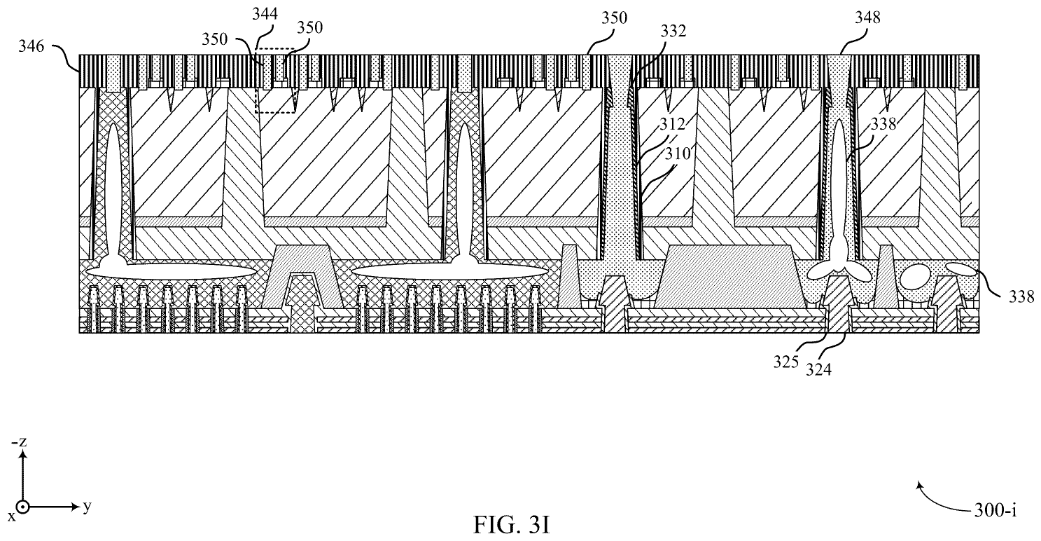

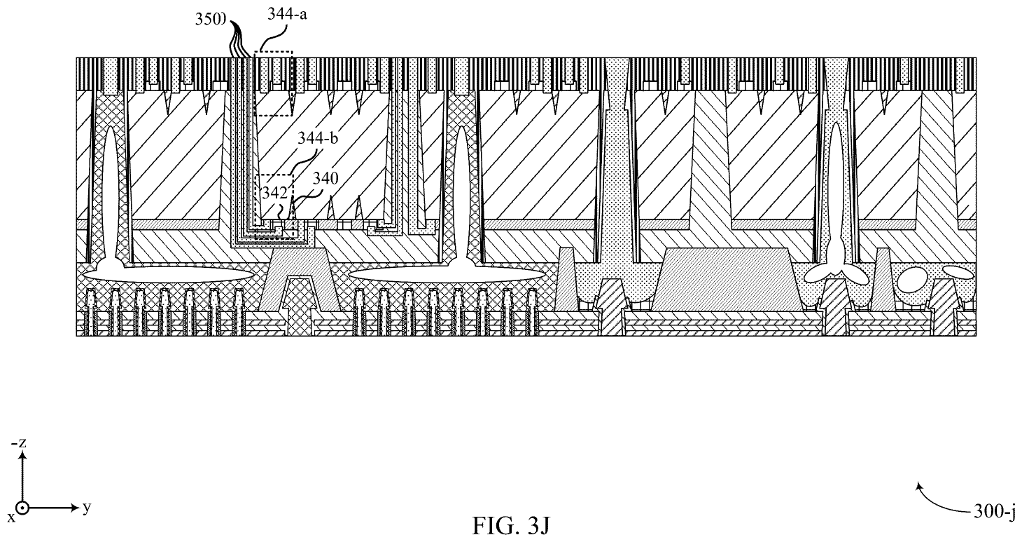

FIGS. 3A through 3J show examples of a material arrangement 300 that may support silicon retention for transistor formation in accordance with examples as disclosed herein. For example, FIGS. 3A through 3J may illustrate aspects of sequences of operations for fabricating aspects of a material arrangement 300, which may be an example of implementing aspects of a system 100 or a memory device 200 as described with reference to FIGS. 1 and 2, among other types of devices. Each of FIGS. 3A, 3B, 3C, 3D, 3E, 3F, 3G, 3H, 3I, and 3J may illustrate aspects of the material arrangement 300 after different subsets of the fabrication operations for forming the material arrangement 300 (e.g., illustrated as a material arrangement 300-a after a first set of one or more fabrication operations, as a material arrangement 300-b after a second set of one or more fabrication operations, and so on). Each of the FIGS. 3A through 3J may illustrate a cross-section of the material arrangement 300 along a z-y plane and viewed from a same +x direction.

Although FIGS. 3A through 3J may illustrate examples of relative dimensions and quantities of various features, aspects of the material arrangement 300 may be implemented with other relative dimensions or quantities of such features in accordance with examples as disclosed herein. In the following description of the material arrangement 300, some methods, techniques, processes, and operations may be performed in different orders or at different times. Further, some operations may be left out of formation of the material arrangement 300, or other operations may be added to the steps described herein. Although some features, components, or materials illustrated in FIGS. 3A through 3J may appear to be in contact or to have a relative orientation or placement (e.g., above, below, to the side of another feature, component, or material), any combination of features, components, and materials in contact or separated (e.g., by one or more intermediate materials) may be used and may be formed according to different relative orientations or placements than those illustrated. Further, the material arrangement 300 may be inversed or rotated by any degree, for example, during fabrication, or within a final product.

In some cases, the operations described with respect to FIGS. 3A through 3J may involve a formation of one or more dielectric materials or insulators. In some cases, dielectric materials or insulative materials may be examples of one or more oxides or different nitrides. The operations may further involve formation of conductive materials (e.g., titanium, tungsten, molybdenum, carbon, among other conductors) and semiconductor materials (e.g., silicon, germanium, silicon-germanium alloy, gallium arsenide, gallium nitride). Operations illustrated in and described with reference to FIGS. 3A through 3J may in some cases be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 3A shows an example of the material arrangement 300 (e.g., as a material arrangement 300-a) after a first set of one or more fabrication operations. For example, the material arrangement 300-a may include a semiconductor material 302, which may be an example of a semiconductor substrate or a semiconductor wafer (e.g., a silicon wafer). In some cases, the semiconductor material 302 may be a solid material extending in the x and y directions, with a height in the z direction, before any operations are performed.

In some examples, the first set of operations may include depositing a material 304 (e.g., a dielectric layer, an oxide layer) over a surface of the semiconductor material 302. One or more trenches may be patterned (e.g., using a mask) and formed using one or more etch operations (e.g., a dry etch, an anisotropic dry etch) to etch through the material 304 and the semiconductor material 302. The trenches may be etched to a depth based on one or more later operations (for example, based on a depth used for building transistors after wafer bonding and back grinding). In some cases, the trenches may at least partially separate portions 306 of the semiconductor material 302 (e.g., such as portions 306-a, 306-b, 306-c, and 306-d), which may represent one or more islands that may be isolated for future transistor formation. Using deposition or another formation process, a material 308 (e.g., an oxide) may fill the trenches and may extend at least partially above a top of the material 304 (or below a bottom in another orientation, or out from a surface of the material 304). In some cases, an edge of the material 308, opposite the material 304, may be planarized (e.g., buffed, grinded down to a flat edge). Planarization processes described herein may in some cases involve a chemical mechanical planarization or polishing (CMP).

FIG. 3B shows an example of the material arrangement 300 (e.g., as a material arrangement 300-b) after a second set of one or more fabrication operations. For example, the second set of one or more fabrication options may include performing one or more etch operations (e.g., dry etch after pattern or mask) to form one or more cavities in the portions 306. The cavities formed may be examples of holes (e.g., round holes) that may be etched to a similar depth as the previously formed trenches, leaving a portion of the semiconductor material 302 at the bottom of each hole. The cavities may be used to form one or more conductive materials, such as contacts or source “plugs” (e.g., for a silicon backside source exhume), through the materials 314, 304, and 302 in a later step. In some cases, the cavities may be used to form a through-silicon via (TSV) that extends through a silicon material of the semiconductor material 302 (e.g., for TSV Con3 connections formed after wafer bonding and back grind).

To facilitate later conductive material formation, each of the cavities may be lined with one or both of a material 310 (e.g., an oxide) or a material 312 (e.g., a nitride). For example, a material 310-a and/or a material 312-a may be deposited in a cavity formed within the portion 306-a of the semiconductor material 302. In some cases, the materials 310 and 312 may represent one or more dielectric materials that may be selected to provide wet edge selectivity during one or more etching or other operations (e.g., as described in FIGS. 3E, 3F, 3I, and 3J), and may be a same and/or different material as the materials 304 and 308. Each cavity may be further etched (e.g., “punched” via an anisotropic dry etch, spacer etch) to expose the semiconductor material 302 at a bottom edge.

In some examples, the second set of one or more fabrication operations may include depositing a material 314 within the cavities that may extend relative to (e.g., above, below, depending on orientation) the material 320 in the y direction. In some examples, the material 314 may be an example of a sacrificial material (e.g., a doped poly-silicon material, carbon or another sacrificial material), which may in some cases be conductive to allow for testing and improved grounding. In some cases, a sacrificial material may refer to a temporary material that is removed at a later step. The material 314 may also be planarized in some examples.

FIG. 3C shows an example of the material arrangement 300 (e.g., as a material arrangement 300-c) after a third set of one or more fabrication operations. For example, the third set of one or more fabrication options may include performing one or more pattern and etch operations to form source isolation and conductive material (e.g., contact Con3) landing pads isolation through the material 314 (e.g., sacrificial poly-silicon material). For example, one or more trenches (e.g., extending from one end across a material to another end along the x direction) or cavities (e.g., holes, tubs extending partially in the x and y directions) may be formed in the material 314 and may at least partially extend into the material 308, where the trenches and/or cavities may be filled with a material 316 (e.g., an oxide), which may be a same or different material than the materials 304, 308, 310 and 312. One or more portions of the material 316 may separate portions of the material 314. After depositing the material 316, the material 316 may be planarized (e.g., using CMP) to expose a surface of the material 314.

In some examples, the third set of one or more fabrication options may include patterning and/or etching cavities (e.g., trenches, holes) for forming one or more landing pads. For example, after an etch process (e.g., dry etch) at least partially into the material 314, a material 318 (e.g., aluminum oxide material, other material) may be deposited in one or more cavities. In some examples, the material 318 may represent a stop etch material for one or more etch operations and a sacrificial material to later be removed for forming additional devices as illustrated in FIG. 3D. For example, the material 318-a may be used for forming a contact landing pad, while a material 318-b may be a sacrificial material for a storage pillar landing pad. In some examples, a portion of a material 316-a may be etched for depositing a material 318-c, which may later be removed for forming a poly-slot (e.g., poly-silicon slot material). The material 318 may be planarized and a material 320 (e.g., a dielectric material, an insulative material, an oxide) may be deposited and planarized.

FIG. 3D shows an example of the material arrangement 300 (e.g., as a material arrangement 300-d) after a fourth set of one or more fabrication operations. In some examples, FIG. 3D may illustrate formation of a material stack 321. For example, the fourth set of one or more fabrication options may include forming, for example, via deposition (e.g., via a tier dep procedure), one or more materials, which may in some examples be alternative materials. The materials may include alternating layers of a material 322 (e.g., an oxide, which may be the same or different from the material 320) and another material, such as a nitride. In some cases, the material 320 may represent a last layer of the layers of material 322.

The fourth set of one or more fabrication operations may further include performing one or more etching operations of the alternating materials to form one or more slits (e.g., narrow trenches) and/or one or more cavities or trenches through the alternating materials. In some cases, one or more additional etch operations (e.g., a replacement gate) may remove the other alternating material (e.g., nitride) from the slit side, which may be replaced with a material 323 (e.g., a conductive material, which may be depositing after depositing an aluminum oxide and a titanium nitride), so that there are alternating materials 322 and 323 in the material stack 321. In some examples, the material 322 may be insulative materials, such as dielectrics, for separating one or more access lines (e.g., word lines, bit lines) formed from the layers of the material 323. In some examples, the etching operations (e.g., before or after adding the material 323) of the material stack 321 may stop at a last layer of the material 320 at the previously deposited materials 318 described with respect to FIG. 3C, which may stop the etch operations. The materials 318 may be exhumed using a different etch operation (e.g., a wet etch) or another etch operation.

In some examples, the fourth set of one or more fabrication operations may including forming one or more contacts 324 (e.g., contacts). For example, after the etching, a material 319 (e.g., an oxide) may be deposited in one or more holes which may be etched to deposit a conductive material (e.g., tungsten, molybdenum, another conductor) to form one or more contacts 324. In some cases, before forming a contact 324, a layer of a material 319 may be deposited within a corresponding cavity (e.g., hole), where the material 319 may be an example of dielectric (e.g., oxide) isolating the contact 324 from word lines of the material 323. One or more pillars 326 (e.g., storage material pillars) may also be formed within one or more of the cavities (e.g., holes). For example, an array of pillars 326 (e.g., a storage pillar array) may be formed where a pillar 326 may include a material 325 (e.g., a storage material, such as a storage nitride, including a blocking oxide between the storage material and the materials 322 and 323), a material 327 (e.g., a poly-silicon channel material including a tunnel oxy-nitride between the channel material of the material 327 and the storage material of the material 325, which may surround a pillar 326 or be part of a pillar 326), and a material 329 (e.g., a filler oxide). In some cases, pillars 326 may include one or more memory cells, for example, within a storage material of the material 325, which may couple with access lines of the material 323. In some examples, a material 328 may also be deposited (e.g., a poly-silicon slot), for example, in an etched portion of the material 316-a (e.g., after removing the stop material of the material 318-c described in FIG. 3C). In some cases, depositing the material 328 may be an example of a slit fill, which may in some cases involve a first dielectric deposited to isolate word line conductors, and depositing one or more additional materials (e.g., depositing a stress relieving grainy poly-silicon material or other low stress materials, such as oxides). In some cases, a stress mitigation of a material may be associated with a height of tier stacks of a device to mitigate deforming of one or more materials. In some examples, the etch operations described herein may involve one or more separate etch operations for forming one or more materials, such as forming the contacts 324 and the pillars 326, or may involve one or more combined etch operations.

In some cases, the material arrangement 300 may be an example of a storage component, such as an array die or an array wafer, that may couple with one or more supporting components, such as a CMOS die or CMOS wafer as described herein. For example, the fourth set of one or more operations may involve forming one or more interconnects and wafer bonding routing, including pads and a bonding surface or interface, relative to (e.g., on, below, above) an edge (e.g., a top, a bottom) of the material stack 321 after planarizing the materials deposited in the trenches and cavities. The materials, contacts 324, and pillars 326 of the material arrangement 300 may be bonded to the CMOS wafer (e.g., using heated bonding procedures). Doing so may couple supportive circuitry, including one or more transistors, with one or more devices, such as with the contacts 324 and pillars 326, to support access operations of memory cells within the pillars 326.

FIG. 3E shows an example of the material arrangement 300 (e.g., as a material arrangement 300-e) after a fifth set of one or more fabrication operations. For example, the fifth set of one or more fabrication options may include one or more operations done at an opposite end of the material arrangement 300 compared to the first through fourth sets of one or more fabrication operations. For example, FIG. 3E may illustrate an inverted view of the material arrangement 300 extending in the-z direction. In some cases, a planarization operation may be performed to remove a portion of the material arrangement 300 (e.g., to back grind a portion of a silicon wafer off of a backside). In some examples, the planarization (e.g., CMP using selective CMP slurry) may remove down to within a margin of ends (e.g., tops) of the material 308 (e.g., oxide isolation TSVs) and the material 314 (e.g., of bottom poly-silicon TSVs from FIG. 3D) to expose ends of the materials 308 and 314 (e.g., for one or more contacts or source material formation). The planarization may be performed in some examples after inverting the material arrangement 300 (e.g., after bonding to the CMOS wafer). The planarization may in some cases leave a portion of the semiconductor material 302 based on a margin in relation to the materials 308 and 314 to control a thickness of the portions 306 of the semiconductor material 302 (e.g., for forming one or more transistors in silicon at a later stage).

The fifth set of one or more fabrication operations may include etching a portion of the material 314. In some cases, a wet etch may be performed to etch back the material 314 that may be selective to the semiconductor material 302 based on doping the material 314 (e.g., to avoid etching a silicon material). Further, the previous deposition of the materials 310 and 312 may protect against unintentional etching of the one or more materials during this process. In some examples, a material 330 (e.g., a thin oxide layer or other insulative material) may be optionally deposited to provide a planarization stop (e.g., CMP stop). A material 332 (e.g., a nitride) may be deposited within the etched portions of the material 314 (and over the optional material 330 if included). In some examples, a surface of the materials 330 and 332 may be planarized or etched down to expose a surface of the silicon for a next step. In some examples, the planarizing or etching operation may expose a clean crystalline silicon surface of the semiconductor material 302 for formation of one or more transistors.

FIG. 3F shows an example of the material arrangement 300 (e.g., as a material arrangement 300-f) after a sixth set of one or more fabrication operations. For example, the sixth set of one or more fabrication options may include depositing a material 334 (e.g., an oxide) over a surface of the semiconductor material 302 and surfaces of the materials 308, 310, 312, and 332 (and over a surface of the material 330 if included). One or more pattern and etch operations may be performed to etch access holes to through the material 334 and in some examples to a top of the material 314 (e.g., a top of poly-silicon plugs formed in holes) for forming a source material as described in FIG. 3G.

FIG. 3G shows an example of the material arrangement 300 (e.g., as a material arrangement 300-g) after a seventh set of one or more fabrication operations. For example, the seventh set of one or more fabrication options may include etching (e.g., exhuming) the material 314 to form one or more cavities, or source areas, containing ends or pads of the pillars 326. A further etch operation may be performed to etch the material 325 (e.g., a cell film, including blocking oxide and storage nitride) and a portion of the material 327 (e.g., a tunnel nitride) to expose a source material of the material 327 (e.g., a channel poly-silicon material) of the pillars 326. In some cases, the etching of the material 314 or of the materials 325 and 327 may involve one or more wet etch operations. In some cases, the etch operation may enable formation of a source material to couple with a channel material of the material 327 of the pillars 326. Additionally, or alternatively, different materials of the pillars may be coupled with the source material. For example, a portion of a tunnel nitride, cell film, storage nitride, or blocking oxide may remain, or one or more materials besides a source material of the material 327 may be coupled with. In some examples, the pillars 326 may include different variety of materials, and a channel material coupled with the deposited source material may represent an example material.

For example, the seventh set of one or more fabrication options may include depositing a material 336 (e.g., a source material, such as an N+ source poly-silicon) within the cavities including the exposed ends of the pillars 326. In some examples, the material 336 may couple one or more of the exposed ends of the pillars 326, and thus may represent a lateral contact source (e.g., a buried, backside, lateral contact source). In some examples, to perform a wet etch (e.g., a tungsten silicide etch), a CMP operation may remove a surface of one or more materials. For example, if the material 336 (e.g., an N+source poly-silicon that is deposited) provides a resistance below a threshold, a source connection material (e.g., a tungsten silicide) may be deposited to lower a resistance of a connection. A CMP may follow to remove a surface of the deposited material 336 and the source connection material to form an isolated contact. Further, if additional materials are deposited (e.g., titanium, titanium nitride, tungsten), an additional CMP operation may be performed to remove a surface of the additional materials.

Additionally, or alternatively, an exposed material channel poly-silicon of the material 327 may be doped (e.g., with a phosphorus rich oxide) and laser annealed (e.g., using a low heat laser anneal without heating one or more CMOS devices). One or more additional operations may include an oxide etch followed by one or more material depositions (e.g., deposition of titanium, titanium nitride, and tungsten). For example, the laser anneal may drive in a material doping (e.g., phosphorus doping) from another material (e.g., from a phosphorous rich oxide) to dope silicon material of the material 337 (e.g., silicon of the poly channel N+). The oxide may then be removed to form an electrical connection between the doped material 337 (e.g., N+ doped poly channel) and one or more additional materials (e.g., titanium, titanium nitride, tungsten). In some cases, one or more of the additional materials (e.g., titanium) may form an ohmic contact with the silicon of the material 337. Thus, the material 336 may be in contact with the material 327 of the pillars 326, or electrically coupled (e.g., directly or indirectly via another material) with the material 327 (e.g., an ohmic contact may be formed on a source side to a channel poly-silicon of the material 336). In some examples, the material 336 may be in contact with the material 320 as well. In some examples, the previous deposition of the material 312 (and similar material 332) may protect the material 310 during one or more of the etch operations to preserve an isolation of the semiconductor material 302 from the material 336.

In some cases, the material 336 may at least partially fill one or more cavities. For example, a deposition process may result in one or more voids 338 being formed in one or more of the cavities (e.g., trapped air gaps in the material 336), where the material 336 may at least partially surround the void to a point of providing an electrical connection. The material 336 may also fill a majority of one or more cavities and/or in some examples the material 336 may also fill the one or more cavities. In some cases, a size of voids 338 may be dependent on a width of an opening at a top of the cavities (e.g., a width of a hole in the material 334), among other factors.

FIG. 3H shows an example of the material arrangement 300 (e.g., as a material arrangement 300-h) after an eighth set of one or more fabrication operations. For example, the second set of one or more fabrication options may include planarizing or polishing (e.g., CMP) down to near a surface of the semiconductor material 302 (e.g., silicon) and may strip the material 334 (e.g., a surface oxide) to expose a surface of the semiconductor material 302. Doing so may expose a clean (e.g., with relatively low impurities) mono-crystalline silicon surface that may be used for forming one or more transistors.

For example, the eighth set of one or more fabrication operations may include forming one or more material portions 340 (e.g., oxide portions, such as oxide wells or oxide isolation trenches) in relation to the semiconductor material 302 (e.g., formed within the silicon) and one or more gate materials 342 (e.g., gate oxide materials) in between the material portions 340 (e.g., formed on top of and in contact with the silicon). Further one or more sources or drains may be formed within the semiconductor material 302 via one or more doping operations or other procedures. Such operations may form one or more transistors 344, where a transistor 344 may include a source portion of the semiconductor material 302, a drain portion of the semiconductor material 302, an active area portion and channel of the semiconductor material 302, and a gate material 342, so that each transistor 344 may extend at least partially out from the semiconductor material 302 (e.g., from a surface of the semiconductor material 302). Each transistor 344 may be separated from other transistors 344 by the material portions 340 or the material 308 isolating portions 306 of the semiconductor material 302. In some examples, a material 346 (e.g., an oxide) may be deposited to cover exposed surfaces of one or more materials, including over the semiconductor material 302 and the newly formed transistors 344. The material 346 may be planarized after being deposited in some examples.

FIG. 3I shows an example of the material arrangement 300 (e.g., as a material arrangement 300-i) after a ninth set of one or more fabrication operations. For example, the ninth set of one or more fabrication options may include etching the material 346 and etching down to the tops of material 314 (e.g., poly-silicon plugs) over the top of the contacts 324. In some cases, one or more etching operations may be performed to remove (e.g., exhume) a portion (e.g., a majority or all of) of the material 314 within the cavities including the ends of the contacts 324 to expose ends of the contacts 324. One or more etching operations may be performed to remove (e.g., exhume) the material 325 (e.g., oxide) over the ends (e.g., tops with relation to FIG. 3I) of the contacts 324 (e.g., contact plugs). The ninth set of one or more fabrication options may further include etching portions of the material 346, the gate material 342, the semiconductor material 302, and the material 308.

A conductive material may be deposited in the etched portions of the materials (e.g., titanium, titanium-nitride, and/or tungsten may be deposited) to form one or more contacts 348 and one or more contacts 350. For example, the contacts 348 may be formed within the cavities including the exposed ends of the contacts 324. The contacts 348 may in some examples include one or more voids 338, or may fill a majority of corresponding etched cavities. In some examples, the previous etching operations may be performed without compromising the material 312 or the material 310 (e.g., one or more insulators) between the contacts 324 and 350 and the semiconductor material 302 (e.g., crystalline silicon). In some examples, a lateral contact may be formed by contacts 348. Further, the contacts 350 may be formed to be in contact with or couple with sources, drains and transistor gates and to provide contacts for power sources.

Further operations may include planarizing (e.g., CMP) a surface of the material 346 and the contacts 348 and 350, and forming one or more other interconnect layers and one or more final metal layers with bond pads, and may include passivation. Thus a final device may include the material arrangement 300-i as, for example, an array wafer bonded with a CMOS wafer (e.g., a CMOS wafer in the positive z direction, or below with respect to FIG. 3I) and one or more metal layers and bond pads at another end (e.g., metal layers and bond pads in the negative z direction on top of the material 346). In some cases, the material arrangement, including an array wafer and CMOS wafer, may represent one or more combinations of front end of line (FEOL) circuitry (e.g., transistor circuitry) and back end of line (BEOL) circuitry (e.g., interconnections). In some examples, the material arrangement 300 may be encapsulated with a packaging material (e.g., a plastic material).

FIG. 3J shows an example of the material arrangement 300 (e.g., as a material arrangement 300-j) that may be an example of an alternate embodiment of the material arrangement 300 illustrated in FIG. 3I and other Figures in FIG. 3A through FIG. 3I. For example, additionally, or alternatively to forming one or more transistors 344, such as a transistor 344-a, at a far end of the portions 306 of the semiconductor material 302 and away from the material stack 321 (in the-z direction), one or more additional transistors 344 may be formed. In some examples, a second set of transistors 344 including a transistor 344-b may be formed on an opposite side of the portions 306 of the semiconductor material 302 in addition to a first set of transistors 344 including a transistor 344-a formed using the operations described with respect to FIG. 3I. For example, referring back to FIG. 3A, the second set of transistors 344 may be formed before depositing the materials 310 and 320 using one or more processes, including but not limited to those processes described herein with respect to forming the first set of transistors 344.

For example, an alternative first set of one or more fabrication options may include planarizing or polishing (e.g., CMP) a surface of the semiconductor material 302 (e.g., silicon) to expose a mono-crystalline silicon surface. One or more material portions 340 (e.g., oxide wells, oxide isolation trenches) and one or more gate materials 342 (e.g., gate oxide materials) may be formed in relation to the original semiconductor material 302 (e.g., in contact with a +z direction side of the semiconductor material 302) and in between the material portions 340. Further, one or more sources or drains may be formed within the semiconductor material 302 via one or more doping operations. Thus, a transistor 344-b of the second set of transistors 344, may include a source portion of the semiconductor material 302 at a +z side of the semiconductor material 302, a drain portion of the semiconductor material 302, an active area portion of the semiconductor material 302 including a channel, and a gate material 342, and may be separated from other transistors 344 by material portions 340 or the material 308 isolating portions 306 of the semiconductor material 302 as described herein. In some examples, the material 304 may be deposited over the semiconductor material 302 and the gate materials 342 and material portions 340 of the second set of transistors 344, and may be planarized (e.g., to a surface or near the gate materials 342). Further, one or more trenches may be etched to form portions 306, and the material 308 may be deposited within the trenches and over the material 304 and the second set of transistors 344. In some examples, the material 308 may act as an insulating material for the second set of transistors 344.

In some examples, one or more etch operations may be performed on the material 346, the material 308, among other materials, during one or more of the formation processes described with respect to FIGS. 3A through 3H to form contacts 350 for the second set of transistors 344 (e.g., to couple with transistors and active regions) on the +z side of the semiconductor material 302. In some cases, any quantity of transistors 344 may be formed within any portion of the portions 306, or within additional semiconductor materials and layers of the material arrangement 300. In some examples, the first set of transistors 344 at the −z side of the semiconductor material 302 (e.g., including the transistor 344-a) may be examples of relatively lower voltage transistors, while the second set of transistors 344 at the +z side of the semiconductor material 302 may be relatively higher voltage transistors, or vice versa.

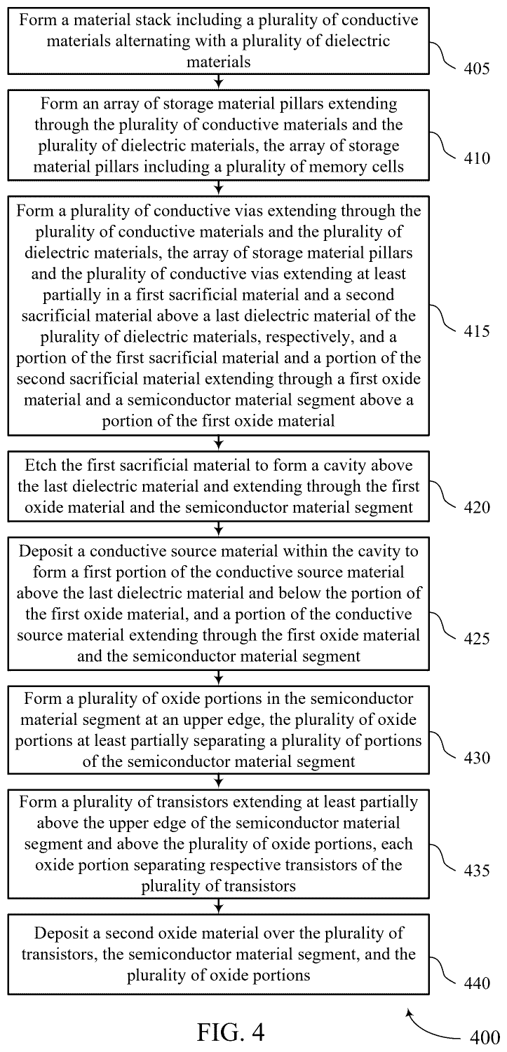

FIG. 4 shows a flowchart illustrating a method or methods 400 that supports silicon retention for transistor formation in accordance with examples as disclosed herein. The operations of method 400 may be implemented by a manufacturing system or one or more controllers associated with a manufacturing system. For example, the operations of method 400 may be performed by a manufacturing system as described with reference to FIGS. 1, 2, and 3A through 3J. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a material stack including a plurality of conductive materials alternating with a plurality of dielectric materials.

At 410, the method may include forming an array of storage material pillars extending through the plurality of conductive materials and the plurality of dielectric materials, the array of storage material pillars including a plurality of memory cells.

At 415, the method may include forming a plurality of conductive vias extending through the plurality of conductive materials and the plurality of dielectric materials, the array of storage material pillars and the plurality of conductive vias extending at least partially in a first sacrificial material and a second sacrificial material above a last dielectric material of the plurality of dielectric materials, respectively, and a portion of the first sacrificial material and a portion of the second sacrificial material extending through a first oxide material and a semiconductor material segment above a portion of the first oxide material.

At 420, the method may include etching the first sacrificial material to form a cavity above the last dielectric material and extending through the first oxide material and the semiconductor material segment.

At 425, the method may include depositing a conductive source material within the cavity to form a first portion of the conductive source material above the last dielectric material and below the portion of the first oxide material, and a portion of the conductive source material extending through the first oxide material and the semiconductor material segment.

At 430, the method may include forming a plurality of oxide portions (e.g., material portions 340, oxide wells, oxide isolation trenches) in the semiconductor material segment at an upper edge, the plurality of oxide portions at least partially separating a plurality of portions of the semiconductor material segment.

At 435, the method may include forming a plurality of transistors extending at least partially above the upper edge of the semiconductor material segment and above the plurality of oxide portions, each oxide portion separating respective transistors of the plurality of transistors.

At 440, the method may include depositing a second oxide material over the plurality of transistors, the semiconductor material segment, and the plurality of oxide portions. Additionally, or alternatively, as discussed in FIGS. 1-4, aspects described in relation to each other may be above, below, or in relation to a surface, one or more edges, or a portion of another aspect. For example, “above” may refer to an object or material being in one direction of another object or material with respect to a plane, while “below” may refer to an object or material being in another direction, where such terms may be reversed for a different orientation. For example, such terms may refer to relation between objects or materials rather than specifically higher or lower placements. Further, extending from a material may refer to extending past a surface or other portion of a material.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for forming a material stack (e.g., material stack 321) including a plurality of conductive materials (e.g., materials 323) alternating with a plurality of dielectric materials (e.g., materials 322); forming an array of storage material pillars (e.g., pillars 326) extending through the plurality of conductive materials and the plurality of dielectric materials, the array of storage material pillars including a plurality of memory cells; forming a plurality of conductive vias (e.g., including one or both of contacts 324 and material 325) extending through the plurality of conductive materials and the plurality of dielectric materials, the array of storage material pillars and the plurality of conductive vias extending at least partially in a first sacrificial material (e.g., material 314 deposited relative to the pillars 326) and a second sacrificial material (e.g., material 314 deposited relative to the contacts 324) above a last dielectric material (e.g., material 320) of the plurality of dielectric materials, respectively, and a portion of the first sacrificial material and a portion of the second sacrificial material extending through a first oxide material (e.g., material 308, one or more of materials 304 and 308) and a semiconductor material segment (e.g., portion 306 of semiconductor material 302) above a portion of the first oxide material; etching the first sacrificial material to form a cavity above the last dielectric material and extending through the first oxide material and the semiconductor material segment; depositing a conductive source material (e.g., material 336) within the cavity to form a first portion of the conductive source material above the last dielectric material and below the portion of the first oxide material, and a portion of the conductive source material extending through the first oxide material and the semiconductor material segment; forming a plurality of oxide portions (e.g., material portions 340, oxide wells, oxide isolation trenches) in the semiconductor material segment at an upper edge, the plurality of oxide portions at least partially separating a plurality of portions of the semiconductor material segment; forming a plurality of transistors (e.g., transistors 344) extending at least partially above the upper edge of the semiconductor material segment and above the plurality of oxide portions, each oxide portion separating respective transistors of the plurality of transistors; and depositing a second oxide material (e.g., material 346) over the plurality of transistors, the semiconductor material segment, and the plurality of oxide portions.

Aspect 2: The method, apparatus, or non-transitory computer-readable medium of aspect 1, further including operations, features, circuitry, logic, means, or instructions, or any combination thereof for etching the second oxide material and the second sacrificial material to form a second cavity extending through the first oxide material, a second semiconductor material segment (e.g., another portion 306 of the semiconductor material 302), and the second oxide material and exposing a respective portion of one or more conductive vias of the plurality of conductive vias; etching a material covering the respective portion (e.g., material 325) of the one or more conductive vias to expose a respective conductive material (e.g., conductive material forming contacts 324) of the one or more conductive vias; and depositing a conductive material (e.g., conductive material forming contacts 348) within the second cavity to form a conductive contact (e.g., contacts 348) extending through the first oxide material, the second semiconductor material segment, and the second oxide material, the conductive contact above the one or more conductive vias.

Aspect 3: The method, apparatus, or non-transitory computer-readable medium of any of aspects 1 through 2, further including operations, features, circuitry, logic, means, or instructions, or any combination thereof for etching the second oxide material to create a plurality of cavities extending through the second oxide material and depositing a conductive material within the plurality of cavities to form a plurality of conductive contacts (e.g., contacts 350) extending through the second oxide material and above the semiconductor material segment.

Aspect 4: The method, apparatus, or non-transitory computer-readable medium of aspect 3, where a portion of the semiconductor material segment between an oxide portion and another oxide portion or a second portion of the first oxide material, the portion of the semiconductor material segment including a source region and a channel region coupled with one or more of the plurality of conductive contacts, and a drain region and a gate material (e.g., gate material 342) under the portion of the semiconductor material segment and coupled with a conductive contact of the plurality of conductive contacts.

Aspect 5: The method, apparatus, or non-transitory computer-readable medium of any of aspects 1 through 4, further including operations, features, circuitry, logic, means, or instructions, or any combination thereof for etching, before forming the material stack, a semiconductor wafer to form a plurality of troughs separating a plurality of semiconductor material segments including the semiconductor material segment and depositing the first oxide material within a trough of the plurality of troughs to form a second portion of the first oxide material (e.g., trenches filled with material 308 for isolation of portions 306), and over the semiconductor material segment to form the portion of the first oxide material (e.g., portion of material 308 between portions 306 of material 302 and material 336 or contacts 348), the second portion of the first oxide material separating the semiconductor material segment from a second semiconductor material segment of the plurality of semiconductor material segments.

Aspect 6: The method, apparatus, or non-transitory computer-readable medium of any of aspects 1 through 5, where the conductive source material is in contact with a channel material (e.g., material 327) of one or more storage material pillars of the array of storage material pillars, the one or more storage material pillars extending at least partially above the last dielectric material (e.g., material 320) of the plurality of dielectric materials.

Aspect 7: The method, apparatus, or non-transitory computer-readable medium of any of aspects 1 through 6, where the conductive source material partially fills the cavity based at least in part on the conductive source material including one or more air gaps (e.g., voids 338).

Aspect 8: The method, apparatus, or non-transitory computer-readable medium of any of aspects 1 through 7, further including operations, features, circuitry, logic, means, or instructions, or any combination thereof for inverting the apparatus after forming the material stack, the array of storage material pillars, and the plurality of conductive vias and before etching the first sacrificial material.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a material stack including a plurality of conductive materials including a plurality of word lines (e.g., formed by layers of material 323) alternating with a plurality of dielectric materials (e.g., layers of material 322); an array of storage material pillars extending through the plurality of conductive materials and the plurality of dielectric materials and coupled with the plurality of word lines, the array of storage material pillars including a plurality of memory cells; a plurality of conductive vias extending through the plurality of conductive materials and the plurality of dielectric materials; a conductive source material under a last dielectric material of the plurality of dielectric materials; a first oxide material under a first portion of the conductive source material; a semiconductor material segment under a portion of the first oxide material, a portion of the conductive source material extending through the semiconductor material segment; a plurality of transistors extending at least partially under a lower edge of the semiconductor material segment, a plurality of oxide portions formed in the semiconductor material segment, each oxide portion separating respective transistors of the plurality of transistors; and a second oxide material under the plurality of transistors, the plurality of oxide portions, and the semiconductor material segment.

Aspect 10: The apparatus of aspect 9, further including: one or more conductive contacts (e.g., contacts 348) under the last dielectric material of the plurality of dielectric materials and under one or more conductive vias of the plurality of conductive vias, the one or more conductive contacts extending through the first oxide material, through a second semiconductor material segment, and through the second oxide material.

Aspect 11: The apparatus of any of aspects 9 through 10, further including: a plurality of conductive contacts (e.g., contacts 350) extending through the second oxide material and to the semiconductor material segment.

Aspect 12: The apparatus of aspect 11, where one or more transistors of the plurality of transistors each include: a respective portion of the semiconductor material segment between an oxide portion and another oxide portion or a second portion of the first oxide material, the respective portion of the semiconductor material segment including a source region, and a channel region coupled with one or more of the plurality of conductive contacts, and a drain region; and a gate material under the respective portion of the semiconductor material segment and coupled with a conductive contact of the plurality of conductive contacts.

Aspect 13: The apparatus of any of aspects 9 through 12, further including: a plurality of semiconductor material segments including the semiconductor material segment; and a second portion of the first oxide material (e.g., trench filled with material 308) separating two of the plurality of semiconductor material segments, the plurality of semiconductor material segments including the semiconductor material segment.

Aspect 14: The apparatus of any of aspects 9 through 13, where the conductive source material is in contact with a channel material (e.g., material 327) of one or more storage material pillars of the array of storage material pillars, the one or more storage material pillars extending at least partially under the last dielectric material of the plurality of dielectric materials.

Aspect 15: The apparatus of any of aspects 9 through 14, where the conductive source material at least partially fills a first cavity (e.g., cavity including ends of pillars 326) under one or more storage material pillars of the array and above the first oxide material and a second cavity (e.g., cavity “plug” extending through material 308 and material 302) including a hole extending through the first oxide material and the semiconductor material segment.

Aspect 16: The apparatus of aspect 15, where the conductive source material partially fills the first cavity, or partially fills the second cavity, or both, based at least in part on the conductive source material surrounding one or more air gaps.

Aspect 17: The apparatus of any of aspects 9 through 16, further including: one or more conductive materials and one or more dielectric materials under the second oxide material; and one or more surface contacts (e.g., solder bumps or contacts formed on metal layers on material 346) under the one or more conductive materials and the one or more dielectric materials.

Aspect 18: The apparatus of any of aspects 9 through 17, further including: one or more conductive materials and one or more dielectric materials above the material stack; and a second plurality of transistors above the material stack and in contact with the one or more conductive materials (e.g., CMOS wafer including conductors and transistors bonded to array wafer).

Aspect 19: The apparatus of any of aspects 9 through 18, further including: a packaging material (e.g., plastic packaging material) covering one or more exposed surfaces of one or more materials of the apparatus.

An apparatus is described. The following provides an overview of aspects of the apparatus as described herein:

Aspect 20: An apparatus, including: a stack of alternating word lines and dielectric layers; an array of stacked memory cells coupled with the stack; a plurality of contacts (e.g., contacts 324) electrically isolated from the stack of alternating word lines and dielectrics by a first insulating material (e.g., material 325); a plurality of semiconductor segments (e.g., portions 306 of semiconductor material 302) electrically isolated from a source channel (e.g., material 336 filling cavity with ends of pillars 326) of the array of stacked memory cells (e.g., of the pillars 326) and from the plurality of contacts by a second insulating material (e.g., one or more of materials 304, 308, and 310); a first plurality of transistors extending at least partially under the plurality of semiconductor segments (e.g., transistors 344 including the transistor 344-a of FIG. 3J); and a second plurality of transistors extending at least partially above the plurality of semiconductor segments and under the stack of alternating word lines and dielectric layers (e.g., transistors 344 including the transistor 344-b of FIG. 3J).

Aspect 21: The apparatus of aspect 20, further including: a second plurality of contacts (e.g., contacts 350 as illustrated in FIGS. 3I and 3J) coupled with the first plurality of transistors and above the plurality of semiconductor segments; and a third plurality of contacts (e.g., contacts 350 as illustrated in FIGS. 3J) coupled with the second plurality of transistors and at least partially below the plurality of semiconductor segments.

Aspect 22: The apparatus of aspect 21, where one or more transistors of the first plurality of transistors and the second plurality of transistors each include: a respective portion of a respective semiconductor material segment between an oxide portion and another oxide portion or the second insulating material, the respective portion of the respective semiconductor material segment including a source region and a channel region coupled with one or more of the second plurality of contacts or the third plurality of contacts, and a drain region; and a gate material in contact with the respective portion of the respective semiconductor material segment and coupled with a conductive contact of the one or more of the second plurality of contacts or the third plurality of contacts.

Aspect 23: The apparatus of any of aspects 20 through 22, where the second plurality of transistors are in contact with the second insulating material (e.g., one or more of materials 304, 308, and 310).

Aspect 24: The apparatus of any of aspects 20 through 23, where the first plurality of transistors are in contact with a third insulating material (e.g., material 346).

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a material stack comprising a plurality of conductive materials comprising a plurality of word lines alternating with a plurality of dielectric materials;
an array of storage material pillars extending through the plurality of conductive materials and the plurality of dielectric materials and coupled with the plurality of word lines, the array of storage material pillars comprising a plurality of memory cells;
a plurality of conductive vias extending through the plurality of conductive materials and the plurality of dielectric materials;
a conductive source material under a last dielectric material of the plurality of dielectric materials;
a first oxide material under a first portion of the conductive source material;
a semiconductor material segment under a portion of the first oxide material, a portion of the conductive source material extending through the semiconductor material segment;
a plurality of transistors extending at least partially under a lower edge of the semiconductor material segment, a plurality of oxide portions formed in the semiconductor material segment, each oxide portion separating respective transistors of the plurality of transistors; and
a second oxide material under the plurality of transistors, the plurality of oxide portions, and the semiconductor material segment.

2. The apparatus of claim 1, further comprising:
one or more conductive contacts under the last dielectric material of the plurality of dielectric materials and under one or more conductive vias of the plurality of conductive vias, the one or more conductive contacts extending through the first oxide material, through a second semiconductor material segment, and through the second oxide material.

3. The apparatus of claim 1, further comprising:
a plurality of conductive contacts extending through the second oxide material and to the semiconductor material segment.

4. The apparatus of claim 3, wherein one or more transistors of the plurality of transistors each comprise:
a respective portion of the semiconductor material segment between an oxide portion and another oxide portion or a second portion of the first oxide material, the respective portion of the semiconductor material segment comprising a source region, and a channel region coupled with one or more of the plurality of conductive contacts, and a drain region; and
a gate material under the respective portion of the semiconductor material segment and coupled with a conductive contact of the plurality of conductive contacts.

5. The apparatus of claim 1, further comprising:
a plurality of semiconductor material segments comprising the semiconductor material segment; and
a second portion of the first oxide material separating two of the plurality of semiconductor material segments, the plurality of semiconductor material segments comprising the semiconductor material segment.

6. The apparatus of claim 1, wherein the conductive source material is in contact with a channel material of one or more storage material pillars of the array of storage material pillars, the one or more storage material pillars extending at least partially under the last dielectric material of the plurality of dielectric materials.

7. The apparatus of claim 1, wherein the conductive source material at least partially fills a first cavity under one or more storage material pillars of the array and above the first oxide material and a second cavity comprising a hole extending through the first oxide material and the semiconductor material segment.

8. The apparatus of claim 7, wherein the conductive source material partially fills the first cavity, or partially fills the second cavity, or both, based at least in part on the conductive source material surrounding one or more air gaps.

9. The apparatus of claim 1, further comprising:
one or more conductive materials and one or more dielectric materials under the second oxide material; and
one or more surface contacts under the one or more conductive materials and the one or more dielectric materials.

10. The apparatus of claim 1, further comprising:
one or more conductive materials and one or more dielectric materials above the material stack; and
a second plurality of transistors above the material stack and in contact with the one or more conductive materials.

11. The apparatus of claim 1, further comprising:
a packaging material covering one or more exposed surfaces of one or more materials of the apparatus.

12. A method for forming an apparatus, comprising:
forming a material stack comprising a plurality of conductive materials alternating with a plurality of dielectric materials;
forming an array of storage material pillars extending through the plurality of conductive materials and the plurality of dielectric materials, the array of storage material pillars comprising a plurality of memory cells;
forming a plurality of conductive vias extending through the plurality of conductive materials and the plurality of dielectric materials, the array of storage material pillars and the plurality of conductive vias extending at least partially in a first sacrificial material and a second sacrificial material above a last dielectric material of the plurality of dielectric materials, respectively, and a portion of the first sacrificial material and a portion of the second sacrificial material extending through a first oxide material and a semiconductor material segment above a portion of the first oxide material;
etching the first sacrificial material to form a cavity above the last dielectric material and extending through the first oxide material and the semiconductor material segment;
depositing a conductive source material within the cavity to form a first portion of the conductive source material above the last dielectric material and below the portion of the first oxide material, and a portion of the conductive source material extending through the first oxide material and the semiconductor material segment;
forming a plurality of oxide portions in the semiconductor material segment at an upper edge, the plurality of oxide portions at least partially separating a plurality of portions of the semiconductor material segment;
forming a plurality of transistors extending at least partially above the upper edge of the semiconductor material segment and above the plurality of oxide portions, each oxide portion separating respective transistors of the plurality of transistors; and
depositing a second oxide material over the plurality of transistors, the semiconductor material segment, and the plurality of oxide portions.

13. The method of claim 12, further comprising:
etching the second oxide material and the second sacrificial material to form a second cavity extending through the first oxide material, a second semiconductor material segment, and the second oxide material and exposing a respective portion of one or more conductive vias of the plurality of conductive vias;
etching a material covering the respective portion of the one or more conductive vias to expose a respective conductive material of the one or more conductive vias; and
depositing a conductive material within the second cavity to form a conductive contact extending through the first oxide material, the second semiconductor material segment, and the second oxide material, the conductive contact above the one or more conductive vias.

14. The method of claim 12, further comprising:
etching the second oxide material to create a plurality of cavities extending through the second oxide material; and
depositing a conductive material within the plurality of cavities to form a plurality of conductive contacts extending through the second oxide material and above the semiconductor material segment.

15. The method of claim 14, wherein one or more transistors of the plurality of transistors each comprise:
a portion of the semiconductor material segment between an oxide portion and another oxide portion or a second portion of the first oxide material, the portion of the semiconductor material segment comprising a source region and a channel region coupled with one or more of the plurality of conductive contacts, and a drain region; and
a gate material under the portion of the semiconductor material segment and coupled with a conductive contact of the plurality of conductive contacts.

16. The method of claim 12, further comprising:
etching, before forming the material stack, a semiconductor wafer to form a plurality of troughs separating a plurality of semiconductor material segments comprising the semiconductor material segment; and
depositing the first oxide material within a trough of the plurality of troughs to form a second portion of the first oxide material, and over the semiconductor material segment to form the portion of the first oxide material, the second portion of the first oxide material separating the semiconductor material segment from a second semiconductor material segment of the plurality of semiconductor material segments.

17. The method of claim 12, wherein the conductive source material is in contact with a channel material of one or more storage material pillars of the array of storage material pillars, the one or more storage material pillars extending at least partially above the last dielectric material of the plurality of dielectric materials.

18. The method of claim 12, wherein the conductive source material partially fills the cavity based at least in part on the conductive source material comprising one or more air gaps.

19. The method of claim 12, further comprising:
inverting the apparatus after forming the material stack, the array of storage material pillars, and the plurality of conductive vias and before etching the first sacrificial material.

20. An apparatus, comprising:
a stack of alternating word lines and dielectric layers;
an array of stacked memory cells coupled with the stack of alternating word lines and dielectric layers;
a plurality of contacts electrically isolated from the stack of alternating word lines and dielectrics by a first insulating material;
a plurality of semiconductor segments electrically isolated from a source channel of the array of stacked memory cells and from the plurality of contacts by a second insulating material;
a first plurality of transistors extending at least partially under the plurality of semiconductor segments; and
a second plurality of transistors extending at least partially above the plurality of semiconductor segments and under the stack of alternating word lines and dielectric layers.

21. The apparatus of claim 20, further comprising:
a second plurality of contacts coupled with the first plurality of transistors and above the plurality of semiconductor segments; and
a third plurality of contacts coupled with the second plurality of transistors and at least partially below the plurality of semiconductor segments.

22. The apparatus of claim 21, wherein one or more transistors of the first plurality of transistors and the second plurality of transistors each comprise:
a respective portion of a respective semiconductor material segment between an oxide portion and another oxide portion or the second insulating material, the respective portion of the respective semiconductor material segment comprising a source region and a channel region coupled with one or more of the second plurality of contacts or the third plurality of contacts, and a drain region; and
a gate material in contact with the respective portion of the respective semiconductor material segment and coupled with a conductive contact of the one or more of the second plurality of contacts or the third plurality of contacts.

23. The apparatus of claim 20, wherein the second plurality of transistors are in contact with the second insulating material.

24. The apparatus of claim 20, wherein the first plurality of transistors are in contact with a third insulating material.
